(19) United States
(12) Patent Application Publication
(10) Pub. No.: US 2012/0013573 A1
(43) Pub. Date: Jan. 19, 2012

(54) PRESSURE SENSITIVE TOUCH CONTROL DEVICE

(75) Inventors: Chen-yu Liu, Jhongli City (CN); Ching-yi Wang, Zhongli City (CN)

(73) Assignee: TPK TOUCH SOLUTIONS INC., Taiwan (CN)

(21) Appl. No.: 13/256,223

(22) PCT Filed: Jul. 1, 2009
(86) PCT No.: PCT/CN2009/072588

§ 371 Date: Sep. 12, 2011

(30) Foreign Application Priority Data
Mar. 13, 2009 (CN) 20091008185.X

(51) Int. Cl. G06F 3/045; G01R 27/26

(52) U.S. Cl. 345/174; 324/660

(57) ABSTRACT

A pressure detectable touch device includes a first substrate, a conductive layer formed on the first substrate, a second substrate, a first electrode pattern, a second electrode pattern, and a microprocessor. When a user touches a touch operation surface of the touch device in such an extent that the conductive layer and the first electrode pattern are not put into physical contact with each other, the touch device is set in a capacitive touch position detection mode. When the user forcibly depresses the touch operation surface of the touch device or carries out a hand writing input operation on the touch operation surface of the touch device, the conductive layer is caused to physically engage the first electrode pattern, setting the touch device in a resistive touch position detection mode.

### FIELD OF THE INVENTION

The present invention relates to a touch device, and in particular to a pressure detectable touch device that combines capacitive and resistive touch control operations.

### BACKGROUND OF THE INVENTION

A resistive touch panel comprises an Indium-Tin-Oxide (ITO) film and a sheet of electrically conductive glass, such as ITO glass, which are spaced from each other by a plurality of properly distributed insulation spacers. With a predetermined driving voltage applied between the ITO film and the ITO glass, when a touching object, such as a stylus, touches and depresses the ITO film, a local depression is formed, which makes a contact with the ITO glass located below thereby inducing a variation of voltage, which, through conversion from analog signal into digital signal, is applied to a microprocessor to be processed for calculation and determination of the position coordinates of the touched point.

A capacitive touch panel generally makes use of variation of electrical capacity coupling between arranged transparent electrodes and a conductor to generate an induced current by which the position coordinates of a touched point can be determined. In the structure of the capacitive touch panel, the outermost layer is a thin transparent substrate that is made of hardening-processed silicon dioxide, and the second layer is an ITO layer. A uniform electric field is built up on the surface of the glass sheet. When a touching object, such as a user's finger, is put in touch with the surface of the transparent substrate that constitutes a screen, the touching object induces electric capacity coupling with the electric field on the outer conductive layer, leading to minute variation of current. Each electrode is responsible for measuring the current from the respective corner and a microprocessor then performs calculation to determine the position coordinates of the touching object.

### SUMMARY OF THE INVENTION

However, the resistive touch panel and the capacitive touch panel both suffer certain limitations on the operations thereof and have drawbacks. The resistive touch panel, although having an advantage of low cost, needs to cause physical contact between a driving conductive layer and a detection conductive layer in the operation thereof. Thus, a pressure must be applied to quite an extent. This often leads to damage of the conductive layers. Also, the sensitivity is low. On the other hand, although having high sensitivity, a capacitive touch panel, due to the operation principle thereof, must be operated with a touching object that is a conductor, such as a user's finger or a touch head, in order to conduct electric current therethrough. The capacitive touch panel cannot be operated with an insulative touching object.

Further, in an electronic device that is equipped with touch input means, hand writing input is commonly adopted. To carry out hand writing input, a user often uses a hand to hold a touch stylus with a predetermined pressure and writes in a regular manner. The touch operation surface of the electronic device may then generate successive position coordinates and a microprocessor calculates and determines a writing trace on the touch operation surface according to the detected position coordinates. General problems that a capacitive touch panel suffers in detecting hand writing input are unsmoothness of writing operation and poor detection result.

Thus, an objective of the present invention is to provide a touch device that switches between different touch position detection modes in accordance with the different ways that a user touches and operates the touch device whereby when a user touches, with a soft force, a touch operation surface of the touch device, the touch device operates in a capacitive touch position detection mode, and when the user forcibly depresses the touch operation surface of the touch device or carries out a hand writing input operation on the touch operation surface of the touch device, the touch device operates in a resistive touch position detection mode.

The technical solution that the present invention adopts to overcome the above discussed problems is a touch device that combines capacitive and resistive touch operation modes for detecting a touch operation that is applied thereto by a touching object. The touch device comprises a conductive layer, a first electrode pattern, a second electrode pattern, and a microprocessor. The conductive layer is formed on a first substrate and is applied with a driving voltage. The first electrode pattern forms a first capacitance with respect to the conductive layer and the second electrode pattern forms a second capacitance with respect to the conductive layer.

When a user touch a touch operation surface of the touch device, the conductive layer is depressed at the operation position, causing a variation of the distance between the conductive layer and the first electrode pattern and also a variation of the distance between the conductive layer and the second electrode pattern. As a consequence, the electric capacity coupling between the conductive layer and the first electrode pattern and the electrical capacity coupling between the conductive layer and the second electrode pattern are changed, setting the touch device to operate in the capacitive touch position detection mode. The microprocessor calculates and determines the operation position of the touching object on the conductive layer according to the change of the electric capacity coupling between the conductive layer and the first electrode pattern and the change of the electric capacity coupling between the conductive layer and the second electrode pattern.

When a user forcibly depresses the touch operation surface of the touch device, or carries out a hand writing input operation on the touch operation surface of the touch device, the conductive layer is depressed at the operation position, making the conductive layer engaging strip-like electrodes of the first electrode pattern so that the distance therebetween is zero, which sets the touch device to operate in the resistive touch position detection mode. The conductive layer, being depressed, is in physical contact with the first electrode pattern and the microprocessor calculates and determines at least one operation position of the touching object on the conductive layer according to variation of voltage of the depressed first electrode pattern.

With the technical solution adopted in the present invention, the pressure detectable touch device of the present invention, when integrated with a simple scanning detection process, is operable in the touch operation mode of either a capacitive touch panel or a resistive touch panel. Constraint in the touching object usable in the conventional resistive touch panel or the capacitive touch panel can be eliminated and the touch control operation of the touch device is simplified. The touch device can be selectively operated in an optimum touch control mode in accordance with different ways of operation. The design provided by the present invention widens the applications of the touch device and features combination of two touch control operation modes.

The present invention can automatically switch to a proper touch position detection mode in accordance with different operation behaviors of users in using the touch device. The present invention is particularly suitable in the applications where hand writing input is applied to the touch device to effectively solve the problems of unsmooth hand writing input and poor detection result found in the conventional capacitive touch panels.

### BRIEF DESCRIPTION OF THE DRAWINGS

The present invention will be apparent to those skilled in the art by reading the following description of preferred embodiments thereof with reference to the drawings, in which:

FIG. 1 shows a system block diagram of a first embodiment in accordance with the present invention;

FIG. 2 shows an exploded view of major constituent components of FIG. 1;

FIG. 3 shows relative positional relationship between a first electrode pattern and a second electrode pattern after a first substrate and a second substrate of FIG. 1 are bonded together;

FIG. 4 shows a cross-sectional view taken along line 4-4 of FIG. 3;

FIG. 5 shows a top plan view of a second substrate of the first embodiment of the present invention;

FIG. 6 shows a top plan view of a second substrate of a second embodiment of the present invention;

FIGS. 7A and 7B schematically demonstrate a touch device in accordance with the present invention operated by a user's finger;

FIG. 8 shows a table listing capacitance corresponding to each touch position demonstrated in FIGS. 7A and 7B;

FIG. 9 schematically shows the touch device of the present invention operated with a touching object;

FIG. 10 shows a system block diagram of the present invention demonstrating the operation by using the touching object of FIG. 9;

FIGS. 11A, 11B, and 11C demonstrate an input operation of hand writing by using a touching object on the touch device in accordance with the present invention;

FIG. 12 shows a system block diagram in association with the hand writing operation demonstrated in FIGS. 11A, 11B, and 11C;

FIG. 13 shows a system block diagram of a third embodiment in accordance with the present invention; and

FIG. 14 shows a cross-sectional view of the third embodiment of the present invention.

### DETAILED DESCRIPTION OF THE PREFERRED EMBODIMENTS

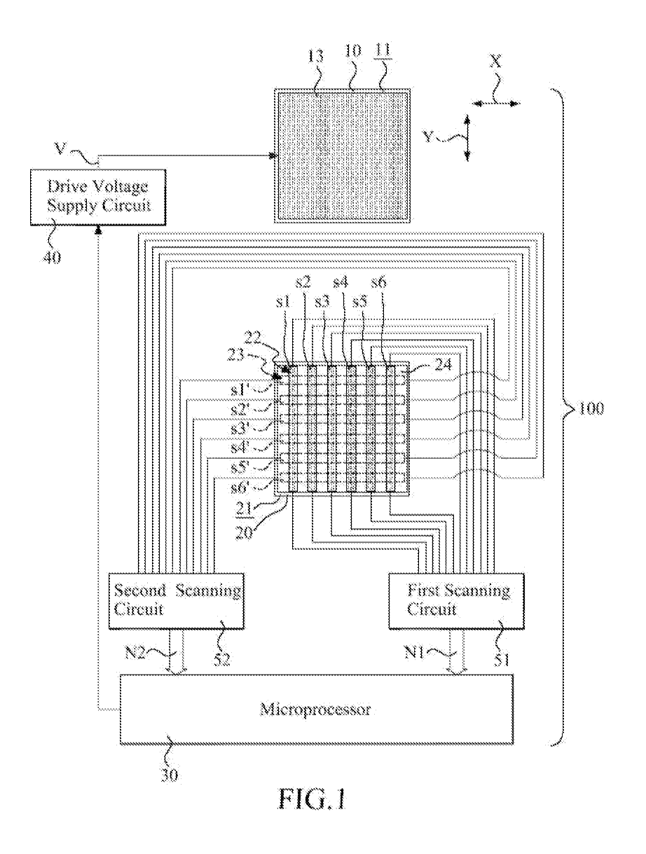

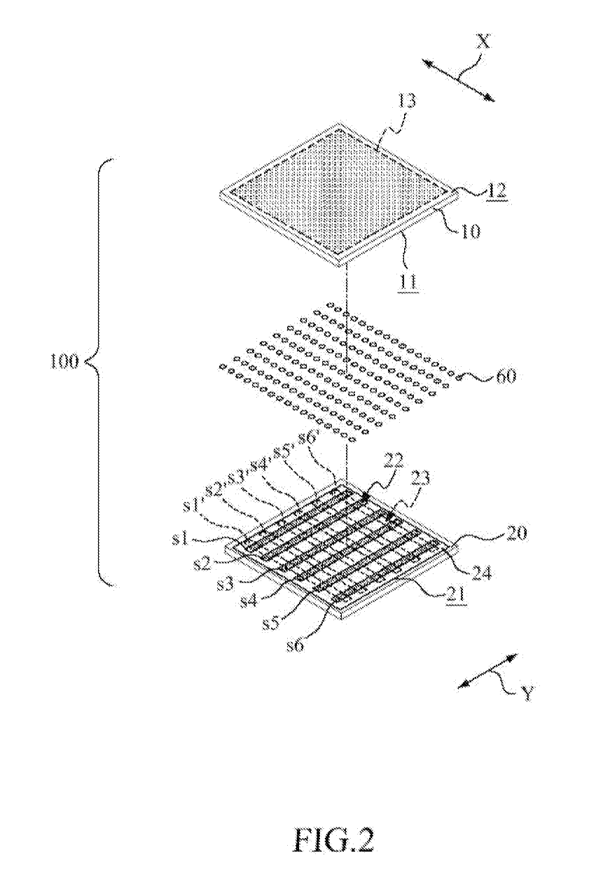

With reference to the drawings and in particular to FIG. 1, which shows a system block diagram of a first embodiment in accordance with the present invention, and FIG. 2, which shows an exploded view of major constituent components of FIG. 1, the present invention provides a touch device 100 that comprises a first substrate 10, a second substrate 20, and a microprocessor 30.

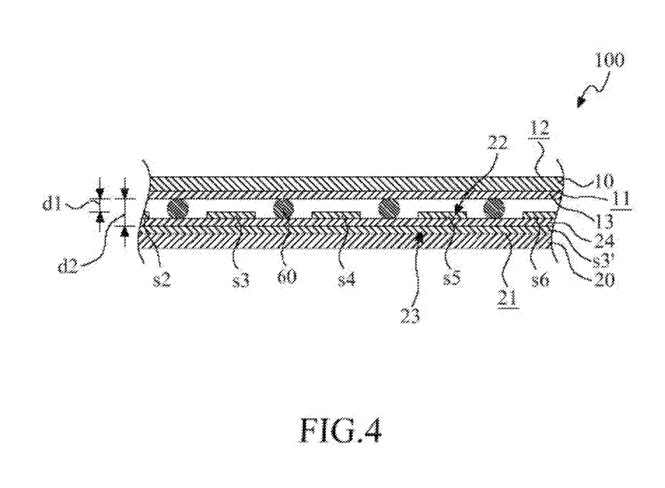

The first substrate 10 comprises a transparent insulation film having a conductive layer bonding surface 11 and a touch operation surface 12 (also see FIG. 4). The conductive layer bonding surface 11 of the first substrate 10 forms a conductive layer 13 thereon, which is made of primarily conductive material. The conductive substance can be for example ITO (Indium Tin Oxide), which forms a transparent electrically-conductive layer.

A driving voltage supply circuit 40 is controlled by the microprocessor 30 to generate and apply a driving voltage V to the conductive layer 13, so that the conductive layer 13 can serve as a driving conductive layer for resistive touch operation.

The second substrate 20 comprises an electrode pattern bonding surface 21 opposing the conductive layer bonding surface 11 of the first substrate 10. A first electrode pattern 22 and a second electrode pattern 23 are formed on the electrode pattern bonding surface 21. As shown in FIGS. 2 and 4, an insulation layer 24 is set between spaces the first electrode pattern 22 and second electrode pattern 23 from each other. The distance between the first electrode pattern 22 and the conductive layer 13 of the first substrate 10 will be referred to as a first predetermined distance d1, while the distance between the second electrode pattern 23 and the conductive layer 13 of the first substrate 10 will be referred to as a second predetermined distance d2.

The first electrode pattern 22 comprises a plurality of strip-like electrodes s1, s2, s3, s4, s5, s6, and induces first capacitance Cx with respect to the conductive layer 13 of the first substrate 10. The strip-like electrodes s1, s2, s3, s4, s5, s6 of the first electrode pattern 22 are substantially parallel to each other and are formed on the insulation layer 24 in such a manner that the strip-like electrodes s1, s2, s3, s4, s5, s6 are spaced from each other. On each of local areas between the insulation layer 24 and the conductive layer 13 of the first substrate 10 where no strip-like electrodes s1, s2, s3, s4, s5, s6 are located, at least one insulation spacer 60 is provided. The insulation spacers 60 function to prevent the conductive layer 13 of the first substrate 10 from directly contacting the first electrode pattern 22.

The second electrode pattern 23 comprises strip-like electrodes s1′, s2′, s3′, s4′, s5′, s6′ and induces a second capacitance Cy with respect to the conductive layer 13 of the first substrate 10. The strip-like electrodes s1′, s2′, s3′, s4′, s5′, s6′ are substantially parallel to each other and are arranged on the electrode pattern bonding surface 21 of the second substrate 20 in such a way that the strip-like electrodes s1′, s2′, s3′, s4′, s5′, s6′ are spaced from each other.

In the embodiment illustrated, the first electrode pattern 22 and the second electrode pattern 23 are each illustratively comprised six strip-like electrodes, but it is apparent that the number of the strip-like electrodes can be varied to be greater or smaller than this number.

In the first electrode pattern 22, the strip-like electrodes s1, s2, s3, s4, s5, s6 are substantially parallel to each other and are spaced from each other by a predetermined distance and extend along a first axis Y. The strip-like electrodes s1′, s2′, s3′, s4′, s5′, s6′ of the second electrode pattern 23 are also parallel to each other, spaced from each other by a predetermined distance and extending along a second axis X. The strip-like electrodes s1, s2, s3, s4, s5, s6 of the first electrode pattern 22 are set at an angle, which can be a right angle or other angles, with respect to the strip-like electrodes s1′, s2′, s3′, s4′, s5′, s6′ of the second electrode pattern 23.

The strip-like electrodes s1, s2, s3, s4, s5, s6 of the first electrode pattern 22 are connected via a first scanning circuit 51 to the microprocessor 30 and the strip-like electrodes s1′, s2′, s3′, s4′, s5′, s6′ of the second electrode pattern 23 are connected via a second scanning circuit 52 to the microprocessor 30.

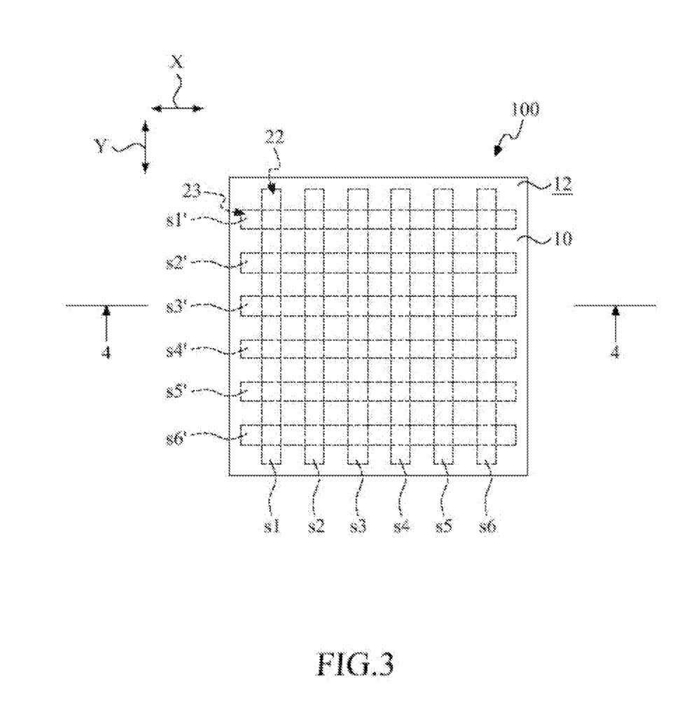

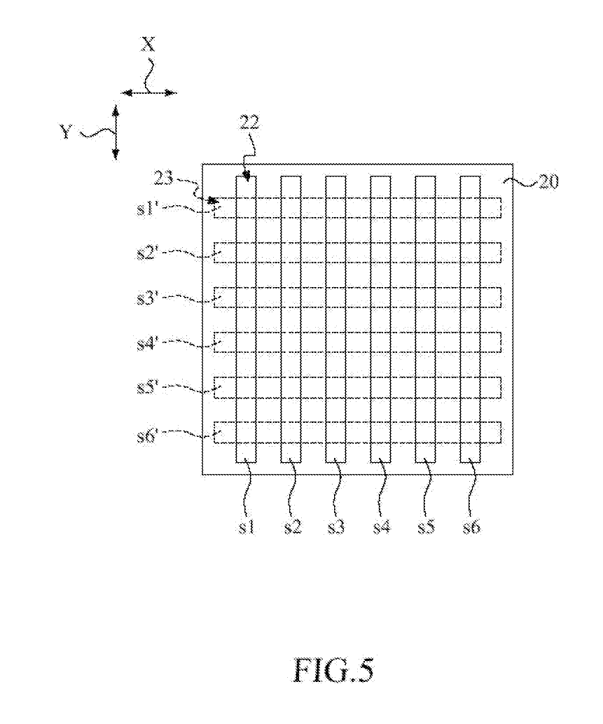

Referring to FIGS. 3 and 5, FIG. 3 shows the relative positional relationship between the first electrode pattern 22 and the second electrode pattern 23 after the first substrate 10 is bonded to the second substrate 20, and FIG. 5 shows a top plan view of the second substrate of the first embodiment of the present invention. As shown, the strip-like electrodes s1, s2, s3, s4, s5, s6 of the first electrode pattern 22 and the strip-like electrodes s1′, s2′, s3′, s4′, s5′, s6′ of the second electrode pattern 23 show an intersecting and overlapping arrangement with each intersection point indicating one of a number of touch positions of the touch device 100.

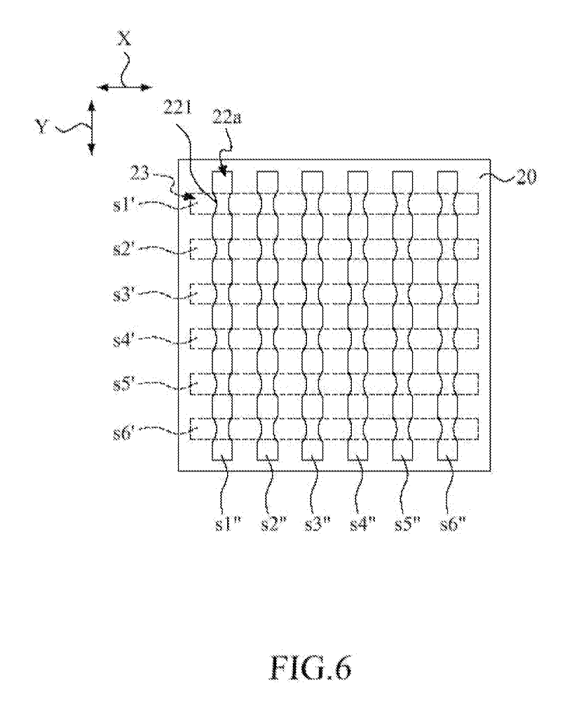

Referring to FIG. 6, which shows a top plan view of the second substrate in accordance with a second embodiment of the present invention, the second substrate 20 of the second embodiment is constructed substantially the same as the counterpart thereof in the first embodiment, whereby identical parts are labeled with the same reference numerals and description thereof will be omitted. A difference between the first and second embodiments resides in that the first electrode pattern 22a comprises strip-like electrodes s1″, s2″, s3″, s4″, s5″, s6″, which are constructed in such a way that each of the strip-like electrodes of the first electrode pattern 22a forms recessed portions 221 corresponding to the intersection points thereof with respect to the strip-like electrodes s1′, s2′, s3′, s4′, s5′, s6′ of the second electrode pattern 23 in order to reduce the shielding that the first electrode pattern 22a may cause on the second electrode pattern 23 and thus improving electrical capacity coupling between the conductive layer 13 and the second electrode pattern 23.

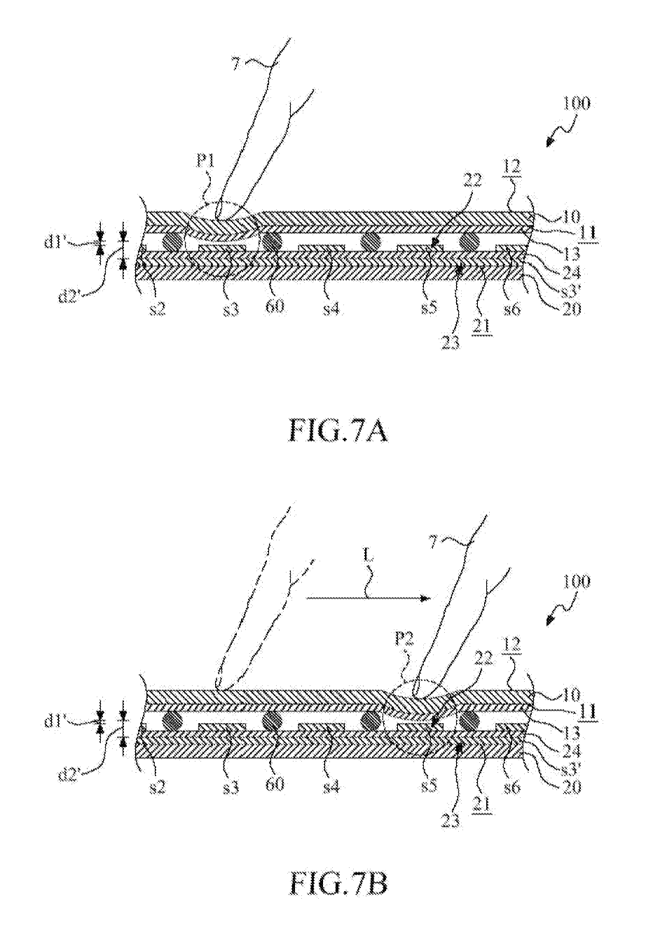

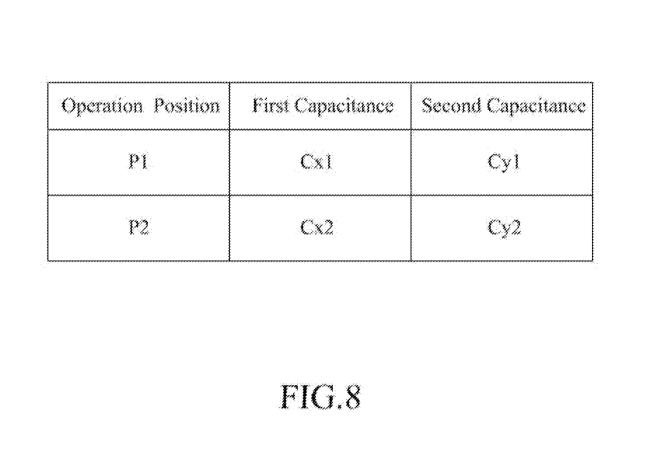

Referring to FIGS. 7A, 7B, and 8, FIGS. 7A and 7B demonstrate the touch device of the present invention operated by a user's finger and FIG. 8 shows a table listing the capacitance corresponding to each touch position demonstrated in FIGS. 7A and 7B.

Firstly, an operation position occurring at the intersection between the strip-like electrode s3 of the first electrode pattern 22 and the strip-like electrode s3′ of the second electrode pattern 23 is referred to as operation position P1, and an operation position occurring at the intersection between the strip-like electrode s5 of the first electrode pattern 22 and the strip-like electrode s3′ of the second electrode pattern 23 is referred to as operation position P2 (top view positions of these operation positions being visible in FIG. 3). In the example illustrated, a touching object 7 that is employed to operate the touch device 100 can be for example a finger, a conductive object, or other suitable operating objects.

The operation of the present invention will now be described. In an idle condition, where no operation is activated, the conductive layer 13 provides electrical capacity coupling with respect to each of the first electrode pattern 22 and the second electrode pattern 23, so that the first capacitance Cx is present between the conductive layer 13 and the first electrode pattern 22 and the second capacitance Cy is present between the conductive layer 13 and the second electrode pattern 23. When the conductive layer 13 and the first electrode pattern 22 and the second electrode pattern 23 are not subjected to touch/depression, no variation of distance therebetween occurs and consequently the electric capacity coupling maintains unchanged.

When the touching object 7 touches an operation position P1 on the touch operation surface 12 of the first substrate 10 (as shown in FIG. 7A) to such an extent that the conductive layer 13 is not in physical contact with the first electrode pattern 22, the conductive layer 13 is depressed at the operation position P1 so that the first predetermined distance d1 between the conductive layer 13 and the first electrode pattern 22 is changed to d1′, where 0<d1′<d1, and the second predetermined distance d2 between the conductive layer 13 and the second electrode pattern 23 changes to d2′, where 0<d2′<d2. Consequently, the first capacitance Cx between the conductive layer 13 and the first electrode pattern 22 is changed to first capacitance Cx1 and the second capacitance Cy between the conductive layer 13 and the second electrode pattern 23 is changed to second capacitance Cy1.

Under this condition, the touch device 100 is operated with a capacitive touch position detection mode, wherein the first scanning circuit 51 scans the variation of electric capacity coupling between the conductive layer 13 and each strip-like electrode s1, s2, s3, s4, s5, s6 of the first electrode pattern 22 and issues a scanning detection signal N1 to the microprocessor 30. The second scanning circuit 52 similarly scans the variation of electric capacity coupling between the conductive layer 13 and each strip-like electrode s1′, s2′, s3′, s4′, s5′, s6′ of the second electrode pattern 23 and issues a scanning detection signal N2 to the microprocessor 30.

The touch device 100 responds to the received variations of the electrical capacity coupling for the first capacitance Cx1 and the second capacitance Cy1 and calculates the operation position of the touching object 7 touching the touch operation surface 12 of the first substrate 10 to thereby determine that the detected operation position corresponds to the operation position P1 at the intersection between the strip-like electrode s3 in the second direction X and the strip-like electrode s3′ in the first direction Y.

When the touching object 7 moves on the touch operation surface 12 of the first substrate 10 along a travel direction L from the operation position P1 to the operation position P2 (as shown in FIG. 7B), the portion of the conductive layer 13 at the operation position P2 is pressurized, making the first predetermined distance d1 between the conductive layer 13 and the first electrode pattern 22 changed to d1′, where 0<d1′<d1 and also making the second predetermined distance d2 between the conductive layer 13 and the second electrode pattern 23 changed to d2′, where 0<d2′<d2. Consequently, the first capacitance Cx between the conductive layer 13 and the first electrode pattern 22 changes to a first capacitance Cx2 and the second capacitance Cy between the conductive layer 13 and the second electrode pattern 23 changes to a second capacitance Cy2. The same scanning detection process as described above can be applied to detect that the touch point is moved to the operation position P2, of which the same description is not necessary herein.

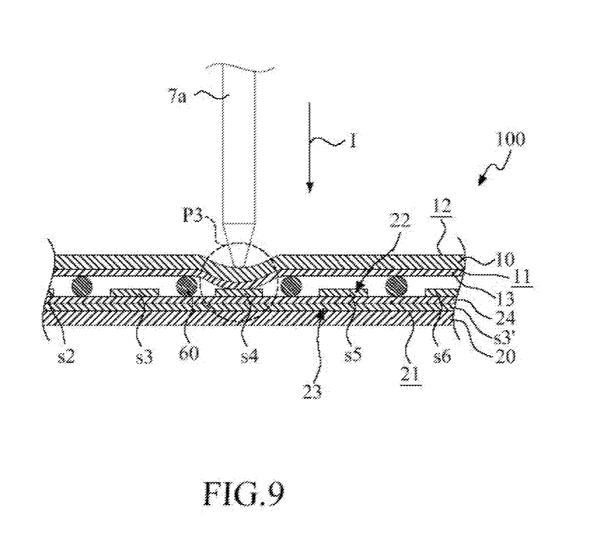

Referring to FIG. 9, which shows a schematic view of the touch device of the present invention being operated with a touching object, firstly, an operation position occurring at the intersection between the strip-like electrode s4 of the first electrode pattern 22 and the strip-like electrode s3′ of the second electrode pattern 23 is referred to as operation position P3. In the instant example, a touching object 7a that is employed to operate the touch device 100 can be a conductive object or a non-conductive object (such as a touch stylus or other suitable objects).

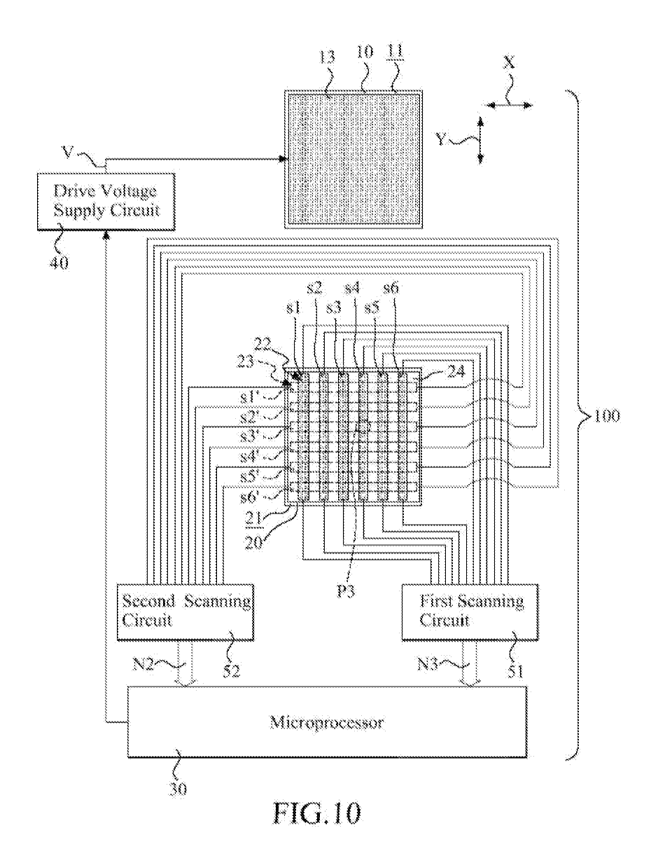

Referring to FIG. 10, which shows a system block diagram of the present invention demonstrating the operation by using the touching object 7a of FIG. 9, when a user uses the touching object 7a to forcibly depress, in a given touching direction I, the touch operation surface 12 of the first substrate 10 at the operation position P3, the conductive layer 13 and the strip-like electrode s4 of the first electrode pattern 22 at the operation position P3 are depressed so that the first predetermined distance dl between them becomes d1=0 (also see FIG. 4).

Under this condition, the touch device 100 is operated with a resistive touch position detection mode, wherein the driving voltage supply circuit 40 supplies the driving voltage V to the conductive layer 13 of the first substrate 10 and the conductive layer 13 transmits the driving voltage V to a corresponding position on the first electrode pattern 22. Thus, when the conductive layer 13 of the first substrate 10, due to depression, becomes in physical contact with the first electrode pattern 22 at the touched position, the driving voltage V is applied to the strip-like electrode s4 of the first electrode pattern 22. The first scanning circuit 51, by performing a scanning operation, detects the variation of voltage in the strip-like electrode s4 of the first electrode pattern 22 and then issues a scanning detection signal N3 to the microprocessor 30. The microprocessor 30 responds to the variation of voltage in the strip-like electrode s4 of the first electrode pattern 22 and calculates the operation position P3 of the touching object 7a operating on the touch operation surface 12 of the first substrate 10.

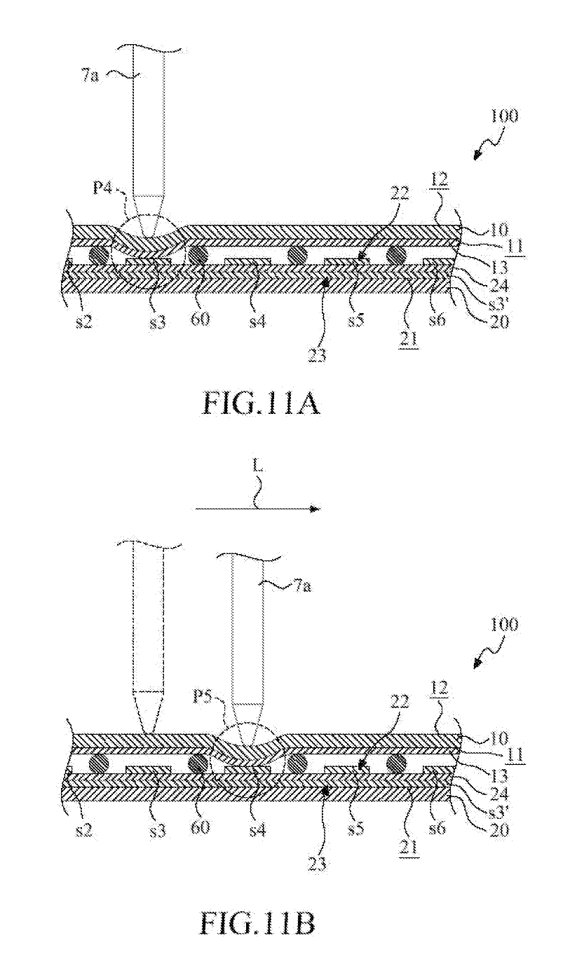

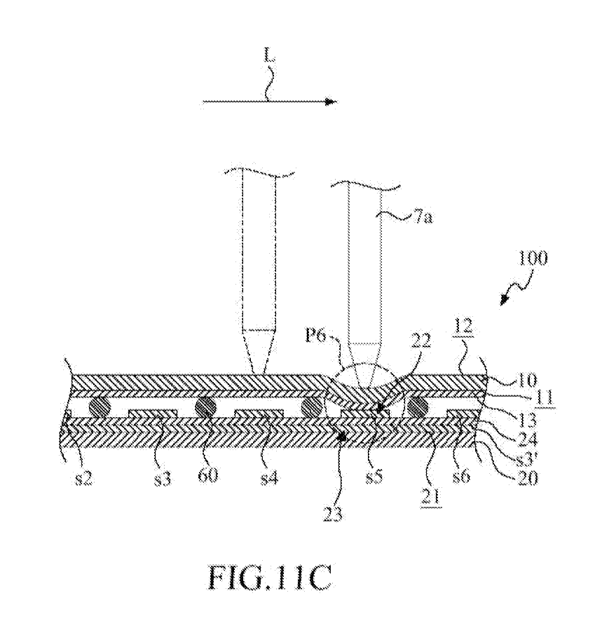

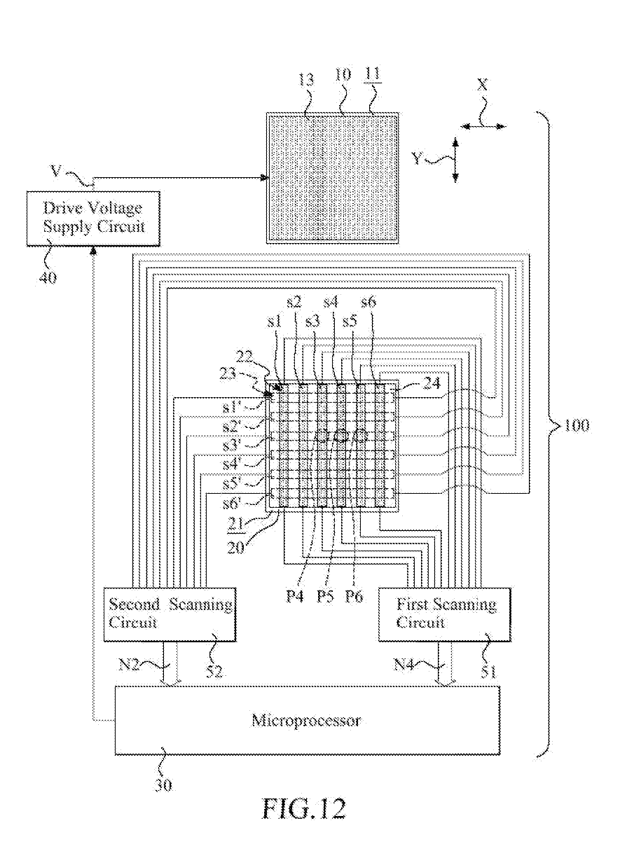

FIGS. 11A, 11B, and 11C demonstrate an input operation of hand writing by using a touching object. FIG. 12 shows a system block diagram in association with the hand writing operation demonstrated in FIGS. 11A, 11B, and 11C.

When a user depresses the touching object 7a against the touch operation surface 12 of the first substrate 10 to effect movement for carrying out hand writing input, the conductive layer 13 and the first electrode pattern 22 are forced into physical contact with each other at operation positions along the writing trace and this activates the touch device 100 to operate in the resistive touch position detection mode. The hand writing input operation causes a trace that comprises multiple operation positions P4, P5, P6 along a movement locus in the travel direction L. At each of the operation positions P4, P5, P6, the driving voltage supply circuit 40 supplies the driving voltage V to the conductive layer 13 of the first substrate 10, which in turn transmits the driving voltage V to the corresponding operation position of the first electrode pattern 22. Thus, when the conductive layer 13 of the first substrate 10 is put in physical contact with the strip-like electrode s3 of the first electrode pattern 22, the driving voltage V is applied to the strip-like electrode s3 of the first electrode pattern 22 and variation of voltage in the strip-like electrode s3 of the first electrode pattern 22 is detected by the scanning operation of the first scanning circuit 51, which in turn issues a scanning detection signal N4 to the microprocessor 30. The microprocessor 30 responds to the variation of voltage in the strip-like electrode s3 of the first electrode pattern 22 and calculates the operation position P4 of the touching object 7a operating on the touch operation surface 12 of the first substrate 10. In this way, the process is repeated for each of the operation positions P4, P5, P6 and the first scanning circuit 51 sequentially scans and detects the scanning detection signal N4 that is the applied to the microprocessor 30. The microprocessor 30, based on the detected operation positions P4, P5, P6, calculates the hand writing trace that the touching object 7a operates on the touch operation surface 12 of the first substrate 10.

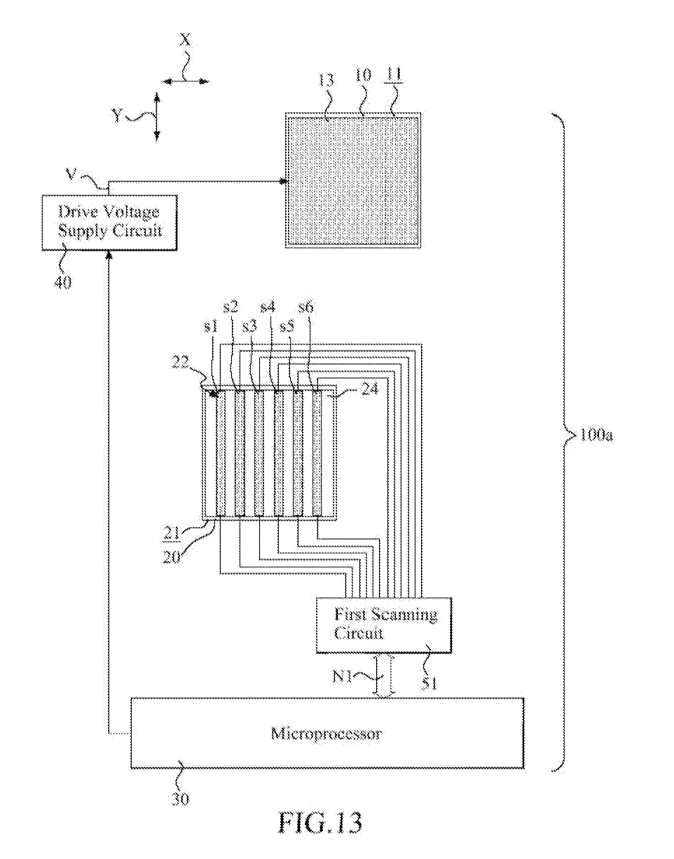

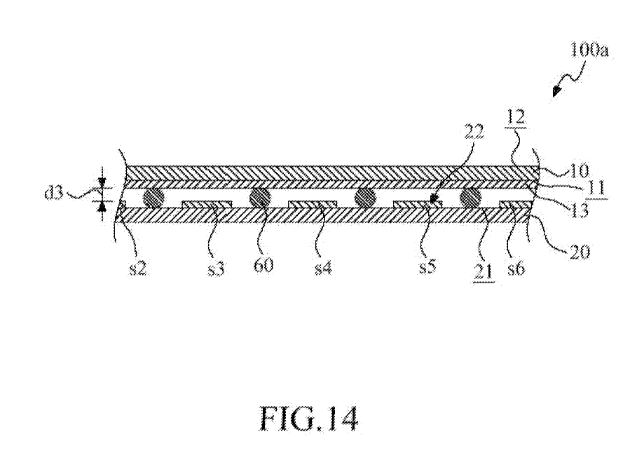

Referring to FIGS. 13 and 14, FIG. 13 shows a system block diagram of a third embodiment in accordance with the present invention and FIG. 14 shows a cross-sectional view of FIG. 13. As shown, a touch device 100a in accordance with the instant embodiment has a construction similar to that of the touch device 100 of the previous embodiment and a difference is that the touch device 100a of the instant embodiment comprises a second substrate 20 which only forms a first electrode pattern 22 that comprises a plurality of strip-like electrodes s1, s2, s3, s4, s5, s6, which is spaced from the conductive layer 13 of the first substrate 10 by a predetermined third distance d3 and is connected to the microprocessor 30 by the first scanning circuit 51. The remaining elements/components that are identical in both embodiments are designated with the same reference numerals and description thereof will be omitted.

The operation of the instant embodiment is the same as that of the previous embodiment, and includes both capacitive and resistive touch control modes. When the touch operation surface 12 of the touch device 100a is not operated as being depressed, the strip-like electrodes s1, s2, s3, s4, s5, s6 of the first electrode pattern 22 are spaced from the conductive layer 13 of the first substrate 10 by the predetermined third distance d3, and the first electrode pattern 22 and the conductive layer 13 induce the first capacitance Cx therebetween.

When a touching object touches the touch operation surface 12 of the first substrate 10 to such an extent that the conductive layer 13 is not put into physical contact with the first electrode pattern 22, the conductive layer 13 is depressed at the operation position so that the third predetermined distance d3 between the conductive layer 13 and the first electrode pattern 22 is changed, leading to variation of the electrical capacity coupling between the conductive layer 13 and the first electrode pattern 22 so that the touch device 100a is set in operation in the capacitive touch detection mode. The first scanning circuit 51 performs scanning to detect the variation of electrical capacitive coupling between the conductive layer 13 and the first electrode pattern 22, and issues a scanning detection signal N1 to the microprocessor 30. The microprocessor 30 responds to the received variation of the electrical capacitive coupling and calculates the operation position that is being depressed or touched.

Similar to the first embodiment, when a touching object forcibly depress the touch operation surface 12 of the touch device 100a and a hand writing input operation is carried out on the touch operation surface 12 of the touch device 100a, the conductive layer 13 and the first electrode pattern 22 are depressed at the operation position, making the predetermined third distance d3=0, and the touch device 100a is thus set in the resistive touch position detection mode. Under this condition, the conductive layer 13 of the first substrate 10 and one of the strip-like electrodes of the first electrode pattern 22 (such as the strip-like electrode s4) are put into contact with each other, allowing the driving voltage V to be applied to the strip-like electrode. The variation of voltage in the strip-like electrode s4 of the first electrode pattern 22 can be detected by being scanned by the first scanning circuit 51, whereby the microprocessor 30 can base on the variation of the voltage to calculate the operation position that is being touched.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A pressure detectable touch device having a touch operation surface adapted to be operated by a touching object, the touch device comprising:
a conductive layer to which a driving voltage is applied;
a first electrode pattern, which is set below the conductive layer and provides a first predetermined distance from the conductive layer;
a second electrode pattern, which is set below the first electrode pattern and provides a second predetermined distance from the conductive layer; and
a microprocessor, which is electrically connected to the conductive layer, the first electrode pattern, and the second electrode pattern;
wherein when the touching object touches the touch operation surface of the touch device at an operation position, the conductive layer is depressed at the operation position, causing a variation of the distance between the conductive layer and the first electrode pattern, which leads to a change of electrical capacitive coupling between the conductive layer and the first electrode pattern and also causing a variation of the distance between the conductive layer and the second electrode pattern, which leads to a change of electrical capacitive coupling between the conductive layer and the second electrode pattern, whereby the touch device is set in a capacitive touch position detection mode in which the microprocessor determines the operation position where the touching object operates the touch operation surface according to the change of electrical capacitive coupling between the conductive layer and the first electrode pattern and the change of electrical capacitive coupling between the conductive layer and the second electrode pattern; and
wherein when the touching object forcibly depresses the touch operation surface of the touch device or when a hand writing input operation is performed on the touch operation surface of the touch device, the conductive layer is depressed at an operation position, making the conductive layer in physical contact with at least one corresponding position of the first electrode pattern, whereby the touch device is set in a resistive touch position detection mode in which the conductive layer applies the driving voltage to the corresponding position of the first electrode pattern and the microprocessor determines at least one operation position on the touch operation surface of the touch device according to variation of voltage in the first electrode pattern.

2. The pressure detectable touch device as claimed in claim 1, wherein the first electrode pattern and the second electrode pattern each comprises a plurality of strip-like electrodes that are parallel to and spaced from each other.

3. The pressure detectable touch device as claimed in claim 2, wherein the strip-like electrodes of the first electrode pattern are connected to the microprocessor via a first scanning circuit and wherein the strip-like electrodes of the second electrode pattern are connected to the microprocessor via a second scanning circuit.

4. The pressure detectable touch device as claimed in claim 2, wherein the microprocessor supplies the driving voltage to the conductive layer through a driving voltage supply circuit.

5. A pressure detectable touch device, comprising:
a first substrate, which comprises a conductive layer bonding surface and a touch operation surface;
a conductive layer, which is formed on the conductive layer bonding surface of the first substrate;
a second substrate, which comprises an electrode pattern bonding surface;
a first electrode pattern, which is set below the conductive layer and provides a first predetermined distance from the conductive layer and is spaced from the conductive layer by insulation spacers; and
a second electrode pattern, which is set below the first electrode pattern and is formed on the electrode pattern bonding surface of the second substrate, the second electrode pattern providing a second predetermined distance from the conductive layer, the second electrode pattern being spaced from the first electrode pattern by an insulation layer;

6. The pressure detectable touch device as claimed in claim 5, wherein the first electrode pattern and the second electrode pattern each comprises a plurality of strip-like electrodes that are parallel to and spaced from each other.

7. The pressure detectable touch device as claimed in claim 6, wherein the strip-like electrodes of the first electrode pattern form recessed portions corresponding to intersections thereof with the strip-like electrodes of the second electrode pattern.

8. The pressure detectable touch device as claimed in claim 6, wherein the device further comprises a microprocessor, which is electrically connected to the conductive layer of the first substrate, the first electrode pattern and the second electrode pattern.

9. The pressure detectable touch device as claimed in claim 8, wherein the strip-like electrodes of the first electrode pattern are connected to the microprocessor via a first scanning circuit and wherein the strip-like electrodes of the second electrode pattern are connected to the microprocessor via a second scanning circuit.

10. The pressure detectable touch device as claimed in claim 8, wherein the microprocessor supplies a driving voltage to the conductive layer through a driving voltage supply circuit.

11. A pressure detectable touch device having a touch operation surface adapted to be operated by a touching object, comprising:
a conductive layer to which a driving voltage is applied;
a first electrode pattern, which is set below the conductive layer and provides a first predetermined distance from the conductive layer;
a microprocessor, which is electrically connected to the conductive layer and the first electrode pattern;
wherein when the touching object touches the touch operation surface of the touch device at an operation position, the conductive layer is depressed at the operation position, causing a variation of the distance between the conductive layer and the first electrode pattern, which leads to a change of electrical capacitive coupling between the conductive layer and the first electrode pattern, whereby the touch device is set in a capacitive touch position detection mode in which the microprocessor determines the operation position where the touching object operates the touch operation surface according to the change of electrical capacitive coupling between the conductive layer and the first electrode pattern; and
wherein when the touching object forcibly depresses the touch operation surface of the touch device or when a hand writing input operation is performed on the touch operation surface of the touch device, the conductive layer is depressed at an operation position, making the conductive layer in physical contact with at least one corresponding position of the first electrode pattern, whereby the touch device is set in a resistive touch position detection mode in which the conductive layer applies the driving voltage to the corresponding position of the first electrode pattern and the microprocessor determines at least one operation position on the touch operation surface of the touch device according to variation of voltage in the first electrode pattern.

12. The pressure detectable touch device as claimed in claim 11, wherein the first electrode pattern comprises a plurality of strip-like electrodes that are parallel to and spaced from each other.

13. The pressure detectable touch device as claimed in claim 12, wherein the strip-like electrodes of the first electrode pattern are connected to the microprocessor via a first scanning circuit.

14. The pressure detectable touch device as claimed in claim 11, wherein the microprocessor supplies the driving voltage to the conductive layer through a driving voltage supply circuit.
